(19) United States
(12) Patent Application Publication
(10) Pub. No.: US 2024/0194530 A1
(43) Pub. Date: Jun. 13, 2024

(54) MANUFACTURING METHOD OF SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP); National University Corporation Tokai National Higher Education and Research System, Nagoya-shi (JP); HAMAMATSU PHOTONICS K.K., Hamamatsu-shi (JP)

(72) Inventors: SHOSUKE NAKABAYASHI, Nisshin-shi (JP); MASATAKE NAGAYA, Nisshin-shi (JP); CHIAKI SASAOKA, Nagoya-shi (JP); ATSUSHI TANAKA, Nagoya-shi (JP); DAISUKE KAWAGUCHI, Hamamatsu-shi (JP); TOSHIKI YUI, Hamamatsu-shi (JP); KEISUKE HARA, Hamamatsu-shi (JP); TOMOMI ARATANI, Hamamatsu-shi (JP)

(21) Appl. No.: 18/515,398

(22) Filed: Nov. 21, 2023

(30) Foreign Application Priority Data
Dec. 12, 2022 (JP) 2022-197856

(51) Int. Cl. H01L 21/78

(52) U.S. Cl. CPC H01L 21/7813

(57) ABSTRACT

In a manufacturing method of a semiconductor device, a first deformation restriction layer and a second deformation restriction layer are formed on a first main surface and a second main surface of a semiconductor substrate, the first main surface being opposite to the second main surface, and the semiconductor substrate having a device structure formed adjacent to the first main surface. A laser beam is applied through the second deformation restriction layer on the second main surface of the semiconductor substrate so as to irradiate a plane extending at a predetermined depth inside of the semiconductor substrate with the laser beam. A device layer that is a part of the semiconductor substrate including the first main surface and the device structure from a remaining layer of the semiconductor substrate along the plane irradiated with the laser beam.

### CROSS REFERENCE TO RELATED APPLICATION

The present application claims the benefit of priority from Japanese Patent Application No. 2022-197856 filed on Dec. 12, 2022. The entire disclosures of the above application are incorporated herein by reference.

### TECHNICAL FIELD

The present disclosure relates to a manufacturing method of a semiconductor device.

### BACKGROUND

As a manufacturing method of a semiconductor device, it has been developed a technique in which, after device structures are formed on one main surface of a semiconductor substrate, laser beam is applied to the inside of the semiconductor substrate to form an altered layer and a device layer in which the device structures have been formed is peeled off from a remaining layer of the semiconductor substrate. When this laser peeling technique is used, the semiconductor substrate from which the device layer has been peeled off can be reused. Thus, the manufacturing costs of the semiconductor device can be reduced.

### SUMMARY

The present disclosure describes a manufacturing method of a semiconductor device using a laser peeling technique. According to an aspect of the present disclosure, a manufacturing method of a semiconductor device may include: forming a first deformation restriction layer and a second deformation restriction layer on a first main surface and a second main surface of a semiconductor substrate, respectively, the first main surface being opposite to the second main surface and the semiconductor substrate having a device structure adjacent to the first main surface; applying a laser beam through the second deformation restriction layer on the second main surface so as to irradiate a plane extending at a predetermined depth inside of the semiconductor substrate with the laser beam; and peeling off a device layer that is a part of the semiconductor substrate including the first main surface and the device structure from a remaining part of the semiconductor substrate along the plane irradiated with the laser beam.

### BRIEF DESCRIPTION OF THE DRAWINGS

Objects, features and advantages of the present disclosure will become more apparent from the following detailed description made with reference to the accompanying drawings, in which like parts are designated by like reference numbers and in which:

FIG. 1 is a diagram illustrating a flow of a manufacturing process of a semiconductor device, including a device structure forming process, a deformation restriction layer forming process, a laser irradiation process, a peeling process, and a dicing process;

FIG. 2 is a diagram schematically illustrating a cross-sectional view of a semiconductor substrate in the manufacturing process of the semiconductor device;

FIG. 3 is a diagram schematically illustrating a cross-sectional view of a unit cell of the device structure formed adjacent to an upper surface of the semiconductor substrate;

FIG. 4 is a diagram schematically illustrating a cross-sectional view of the semiconductor substrate in the manufacturing process of the semiconductor device;

FIG. 5 is a diagram schematically illustrating a cross-sectional view of the semiconductor substrate in the manufacturing process of the semiconductor device;

FIG. 6 is a diagram schematically illustrating a cross-sectional view of the semiconductor substrate in the manufacturing process of the semiconductor device;

FIG. 7 is a diagram schematically illustrating a cross-sectional view of the semiconductor substrate in the manufacturing process of the semiconductor device;

FIG. 8 is a diagram schematically illustrating an enlarged cross-sectional view of a part of the semiconductor substrate in the vicinity of a peripheral end of a lower surface of the semiconductor substrate in the manufacturing process of the semiconductor device;

FIG. 9 is a diagram schematically illustrating a cross-sectional view of the semiconductor substrate in the manufacturing process of the semiconductor device; and

FIG. 10 is a diagram schematically illustrating a cross-sectional view of the semiconductor substrate in the manufacturing process of the semiconductor device.

### DETAILED DESCRIPTION

In a manufacturing method of a semiconductor device, when a laser peeling technique is used, a semiconductor substrate after a device layer is peeled off can be reused, and the manufacturing costs of the semiconductor device thus can be reduced.

However, when the semiconductor substrate is irradiated with a laser beam to form an altered layer, a crystal structure may be collapsed due to the laser irradiation and atoms forming the semiconductor may be vaporized in a portion of the semiconductor substrate where the altered layer is formed. For example, in a case where the semiconductor substrate is formed of a nitride semiconductor, it is known that nitrogen gas is generated in the position of the altered layer. When gas is generated inside the semiconductor substrate, the semiconductor substrate expands. As a result, the semiconductor substrate is deformed. The deformation of the semiconductor substrate causes variations in the focusing position of the laser beam or causes damage to the semiconductor substrate.

The present disclosure provides a technique for restricting deformation of a semiconductor substrate in a manufacturing method of a semiconductor device using a laser peeling technique.

According to an aspect of the present disclosure, a manufacturing method of a semiconductor device may include: forming a first deformation restriction layer and a second deformation restriction layer on a first main surface and a second main surface of a semiconductor substrate, respectively, the first main surface being opposite to the second main surface, and the semiconductor substrate having a device structure formed adjacent to the first main surface; applying a laser beam through the second deformation restriction layer on the second main surface of the semiconductor substrate so as to irradiate a plane extending at a predetermined depth inside of the semiconductor substrate with the laser beam; and peeling off a device layer that is a part of the semiconductor substrate including the first main surface and the device structure from a remaining part of the semiconductor substrate along the plane irradiated with the laser beam.

For example, the semiconductor substrate may be various types of semiconductor substrates containing atoms that are vaporized by irradiation with the laser beam. The type of the device structure may not be particularly limited. For example, the device structure may be a structure for forming a metal oxide semiconductor field effect transistor (MOSFET), an insulated gate bipolar transistor (IGBT), a high electron mobility transistor (HEMT), or a diode.

In the manufacturing method described above, the first deformation restriction layer and the second deformation restriction layer are formed on the first main surface and the second main surface of the semiconductor substrate before the applying of the laser beam. Therefore, even if gas is generated inside the semiconductor substrate during the applying of the laser beam, it is less likely that the semiconductor substrate will be deformed.

Embodiments of the present disclosure will be described more in detail with reference to the drawings.

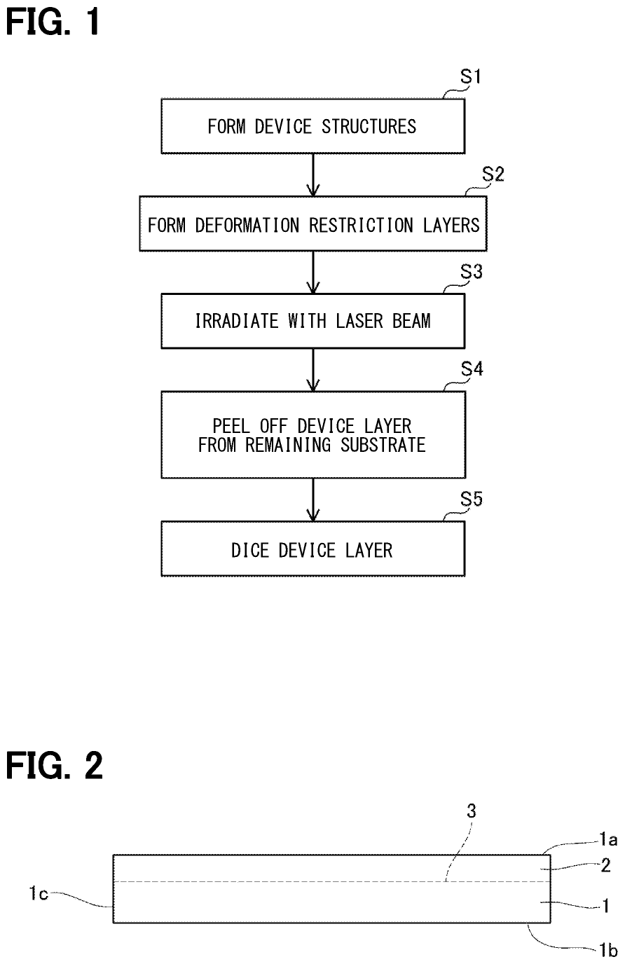

In an embodiment, as shown in FIG. 1, a manufacturing method of a semiconductor device using a laser peeling technique includes a device structure forming process S1, a deformation restriction layer forming process S2, a laser application process S3, a peeling process S4, and a dicing process S5. In this manufacturing method, a plurality of semiconductor devices, which will also be referred to as chips, can be produced by performing these processes on a semiconductor substrate 1 shown in FIG. 2.

As shown in FIG. 2, the semiconductor substrate 1 has an upper surface 1a and a lower surface 1b which are flat surfaces and extend in parallel to each other. The upper surface 1a and the lower surface 1b will also be referred to as a first main surface and a second main surface, respectively. The semiconductor substrate 1 further includes a side surface 1c that is orthogonal to the upper surface 1a and the lower surface 1b and connects the upper surface 1a and the lower surface 1b. The semiconductor substrate 1 is not particularly limited, but may be, for example, a nitride semiconductor substrate. Specifically, the semiconductor substrate 1 may be a substrate made of, for example, gallium nitride (GaN). As will be described later, a plane 3 extending at a predetermined depth inside the semiconductor substrate 1 is a plane irradiated with a laser beam L, that is, a plane on which a plurality of focal points of the laser beam L converge. Hereinafter, the plane 3 is referred to as the focusing plane. The depth of the focusing plane 3 is closer to the upper surface 1a than to the lower surface 1b of the semiconductor substrate 1. In the present disclosure, a part of the semiconductor substrate 1 above the focusing plane 3, that is, a part peeled off from the semiconductor substrate 1 is referred to as a device layer 2.

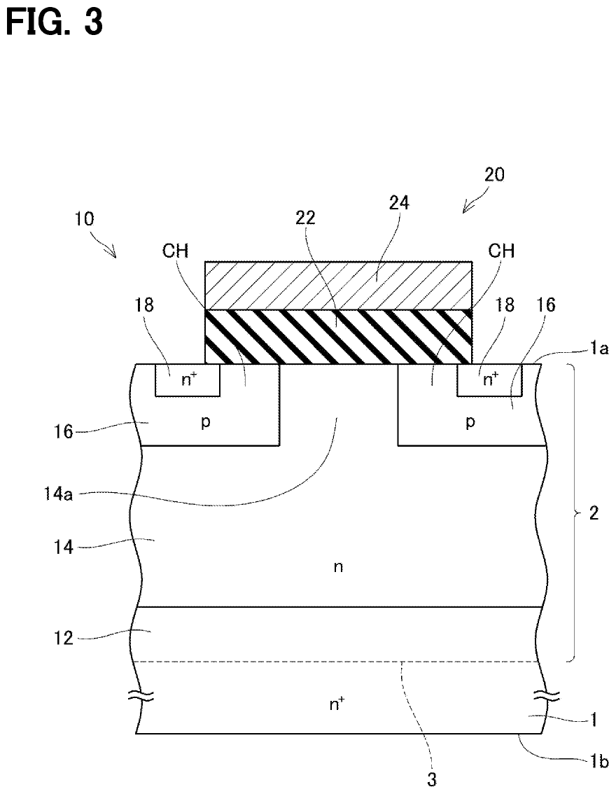

In the device structure forming process (S1 in FIG. 1), a device structure 10 is formed in the device layer 2 of the semiconductor substrate 1. FIG. 3 shows a unit cell of the device structure 10 formed in the device layer 2 of the semiconductor substrate 1 after the device structure forming process is performed. Although not particularly limited, the device structure 10 may be, for example, a vertical metal oxide semiconductor field effect transistor (MOSFET).

The device structure 10 includes an n⁺-type drain region 12, an n-type drift region 14, a p-type body region 16, an n⁺-type source region 18, and a planar type MOS structure 20.

The drain region 12 is provided at a position exposed on the lower surface 1b of the semiconductor substrate 1. The drift region 14 is provided between the drain region 12 and the body region 16. A part of the drift region 14 disposed at a position exposed on the upper surface 1a of the semiconductor substrate 1 is referred to as a JFET region 14a. The body region 16 is provided at a position exposed on the upper surface 1a of the semiconductor substrate 1, and is disposed so as to separate the drift region 14 and the source region 18 from each other. A part of the body region 16 located between the JFET region 14a of the drift region 14 and the source region 18 is referred to as a channel region CH. The source region 18 is provided at a position exposed on the upper surface 1a of the semiconductor substrate 1.

The MOS structure 20 is disposed so as to cover a part of the upper surface 1a of the semiconductor substrate 1. The MOS structure 20 includes a gate insulating film 22 and a gate electrode 24. The gate electrode 24 faces the channel region CH of the body region 16 with the gate insulating film 22 interposed therebetween. In the device structure 10, the electron density of an inversion layer generated in the channel region CH of the body region 16 is controlled in accordance with a gate voltage applied to the gate electrode 24.

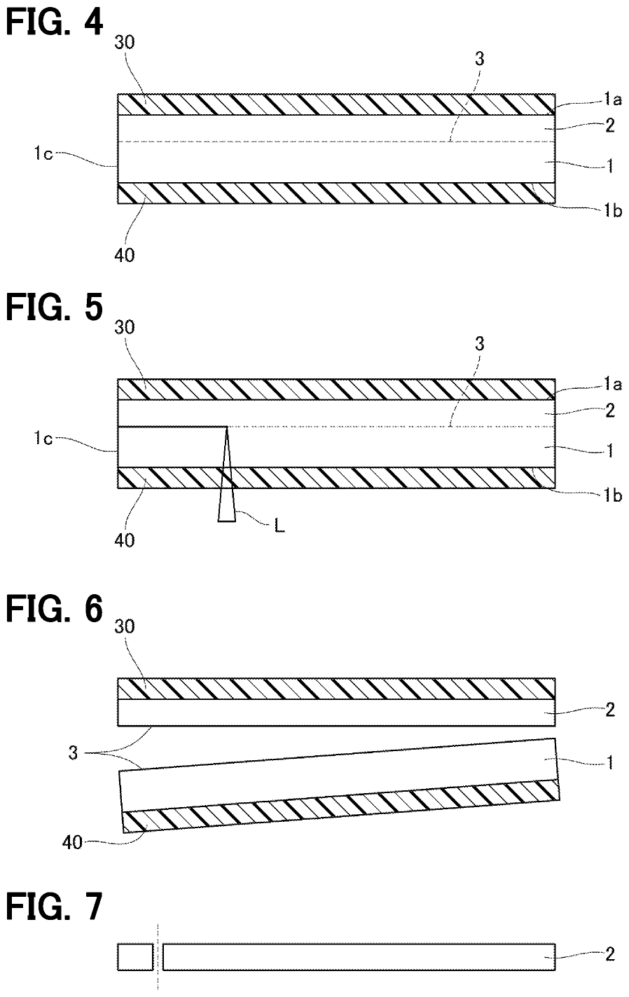

As shown in FIG. 4, in the deformation restriction layer forming process (S2 in FIG. 1), a first deformation restriction layer 30 is formed on the entire upper surface 1a of the semiconductor substrate 1, and a second deformation restriction layer 40 is formed on the entire lower surface 1b of the semiconductor substrate 1. The material of the deformation restriction layers 30 and 40 is not particularly limited. The deformation restriction layers 30 and 40 may be made of a material having a Young's modulus higher than that of the semiconductor substrate 1 or a material having a Young's modulus lower than that of the semiconductor substrate 1. The first deformation restriction layer 30 and the second deformation restriction layer 40 may be made of the same material, or made of different materials.

The first deformation restriction layer 30 may be made of an organic material in consideration of stress reduction with respect to the device structure 10 formed on the upper surface 1a of the semiconductor substrate 1 and adhesiveness to the upper surface 1a of the semiconductor substrate 1. For example, the first deformation restriction layer 30 may be made of a resin, such as a thermosetting resin or an ultraviolet curable resin. Alternatively, the first deformation restriction layer 30 may be a surface protective tape, which is widely used in a semiconductor manufacturing process.

The second deformation restriction layer 40 may be made of a material similar to that of the first deformation restriction layer 30, or may be made of a ceramic material, a metal material, a crystal material, or a combination thereof. These materials may be directly bonded to the lower surface 1b of the semiconductor substrate 1, or may be deposited on the lower surface 1b of the semiconductor substrate 1 using a deposition technique. Examples of the deposition technique include a sputtering technique, a vapor deposition technique, a plasma deposition technique, or the like. In this example, each of the first deformation restriction layer 30 and the second deformation restriction layer 40 is made of a resin. The thicknesses of the first deformation restriction layer 30 and the second deformation restriction layer 40 are not particularly limited, and may be appropriately adjusted so as to restrict deformation of the semiconductor substrate 1 in a laser irradiation process described later.

As shown in FIG. 5, in the laser irradiation process (S3 in FIG. 1), the focusing plane 3 extending at a predetermined depth inside the semiconductor substrate 1 is irradiated with a laser beam L. The laser beam L is applied from the lower surface 1b side on which the device structures 10 are not formed so as to be focused on the predetermined depth of the semiconductor substrate 1. The laser beam L has a wavelength range that has transparency with respect to the semiconductor substrate 1 (e.g., the gallium nitride substrate in this example) and the second deformation restriction layer 40. The laser beam L is not particularly limited, but may be a visible light laser beam, for example, a green laser beam. In this example, the crystal forming the semiconductor substrate 1 is a single crystal of gallium nitride. At the position of the focal point, the crystal forming the semiconductor substrate 1 is heated and decomposed, so that an altered layer is formed. The strength of the altered layer is lower than that of the crystal forming the semiconductor substrate 1. Therefore, the strength of the altered layer is lower than that of the surrounding crystals.

Nitrogen gas is generated during a process where the altered layer is formed inside the semiconductor substrate 1. When the nitrogen gas is generated inside the semiconductor substrate 1, the semiconductor substrate 1 tends to expand and deform. However, the deformation restriction layers 30 and 40 are formed on both surfaces 1a and 1b of the semiconductor substrate 1. Therefore, even if the nitrogen gas is generated inside the semiconductor substrate 1, deformation of the semiconductor substrate 1 is restricted. As a result, it is possible to suppress a situation in which the focusing position of the laser beam L, that is, the laser irradiation position deviates in the semiconductor substrate 1, or a situation that the semiconductor substrate 1 is damaged.

As shown in FIG. 6, in the peeling process (S4 in FIG. 1), the device layer 2 in which the device structures 10 have been formed is peeled off from the remaining layer of the semiconductor substrate 1 along the focusing plane 3 irradiated with the laser beam L. Since the strength of the focusing plane 3 is lowered due to the formation of the altered layer, the device layer 2 is favorably peeled off from the remaining layer of the semiconductor substrate 1. In this peeling process, the deformation restriction layers 30 and 40 are kept on both the first and second surfaces 1a and 1b of the semiconductor substrate 1. In this case, the deformation restriction layers 30 and 40 can also function as a surface protective film in the peeling process. Note that, after the device layer 2 is peeled off, the semiconductor substrate 1 is reused for manufacturing semiconductor devices. For example, after polishing, etching, and the like are performed on the peeled surface of the semiconductor substrate 1 from which the device layer 2 has been peeled off, a device layer is formed again on the peeled surface using an epitaxial crystal growth technique. Thus, the device structures 10 can be formed in the newly formed device layer 2.

As shown in FIG. 7, in the dicing process (S5 in FIG. 1), a polishing process, an electrode forming process, and the like are performed on the device layer 2 that has been peeled off from the semiconductor substrate 1. Thereafter, a plurality of devices (also referred to as dies) are cut out from the device layer 2. In this way, the semiconductor devices are produced.

Other features and modifications of the manufacturing method will be described hereinafter.

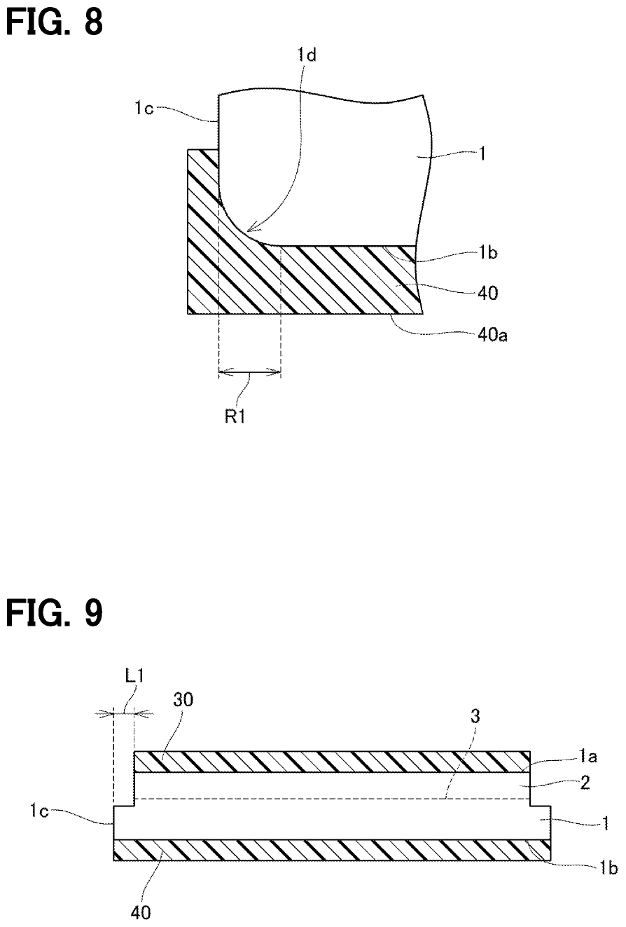

FIG. 8 is an enlarged cross-sectional view of a main part of the semiconductor substrate 1 in the vicinity of a peripheral end of the lower surface 1b. In general, the peripheral end of a main surface of a semiconductor substrate often has a curved shape. Therefore, as shown in FIG. 8, the peripheral end of the lower surface 1b of the semiconductor substrate 1 has a curved end surface 1d extending between the lower surface 1b and the side surface 1c. In the laser irradiation process, the laser beam L is applied in a direction orthogonal to the lower surface 1b of the semiconductor substrate 1. Therefore, in a case where the second deformation restriction layer 40 is not formed, the laser beam L is refracted at the curved end surface 1d of the semiconductor substrate 1. As a result, a situation may occur in which the laser beam L is not condensed at both ends of the light focusing plane 3 of the semiconductor substrate 1.

As shown in FIG. 8, the second deformation restriction layer 40 is formed to extend laterally beyond the side surface 1c of the semiconductor substrate 1 and to cover the curved end surface 1d of the semiconductor substrate 1. The difference in refractive index between the second deformation restriction layer 40 and the semiconductor substrate 1 is smaller than the difference in refractive index between the air and the semiconductor substrate 1. Therefore, in the case where the second deformation restriction layer 40 is formed so as to cover the curved end surface 1d of the semiconductor substrate 1, refraction of the laser beam L transmitted through the interface between the second deformation restriction layer 40 and the end curved surface 1d of the semiconductor substrate 1 is suppressed. When the semiconductor substrate 1 is viewed along the laser application direction, that is, in the direction orthogonal to the lower surface 1b, a flat surface 40a of the second deformation restriction layer 40 is present in the range R1 in which the curved end surface 1d of the semiconductor substrate 1 is present. Therefore, the refraction of the laser beam L when entering the second deformation restriction layer 40 can also be suppressed. As a result, in the laser irradiation process, the laser beam L can be favorably focused also on both end portions of the light focusing plane 3 of the semiconductor substrate 1. When the laser beam L is favorably focused on both end portions of the light focusing plate 3 of the semiconductor substrate 1, the altered layer can be formed to extend to the side surface 1c of the semiconductor substrate 1. Therefore, since the altered layer is exposed on the side surface 1c of the semiconductor substrate 1, a part of the nitrogen gas generated in the laser irradiation process can be satisfactorily discharged from the side surface 1c of the semiconductor substrate 1. As a result, even if the nitrogen gas is generated inside the semiconductor substrate 1, deformation of the semiconductor substrate 1 can be suppressed. In order to satisfactorily discharge the nitrogen gas from the side surface 1c of the semiconductor substrate 1, it is desirable that a portion of the side surface 1c of the semiconductor substrate 1 on which the focusing plane 3 is exposed is not covered with the deformation restriction layers 30 and 40.

As shown in FIG. 9, before the laser irradiation process, a removal processing process may be performed. In the removal processing process, the peripheral end of the upper surface 1a of the semiconductor substrate 1 is removed so that an upper part of the side surface 1c adjacent to the upper surface 1a is positioned more to inside of the semiconductor substrate 1 than a lower part of the side surface 1c adjacent to the lower surface 1b. In other words, the upper surface 1a of the semiconductor substrate 1 is subjected to edge trimming so that the peripheral end of the upper surface 1a is positioned inside the peripheral end of the lower surface 1b in the plan view of the semiconductor substrate 1. The removal processing process may be performed before the deformation restriction layer forming process or may be performed after the deformation restriction layer forming process. In the semiconductor substrate 1 after the removal processing process, the offset length L1 between the upper part of the side surface 1c adjacent to the upper surface 1a and the lower part of the side surface 1c adjacent to the lower surface 1b in a planar direction along the main surface of the semiconductor substrate 1 is larger than the width of the range R1 (see FIG. 8) in which the curved end surface 1d of the lower surface 1b is present. The focusing plane 3 of the semiconductor substrate 1 is exposed on the upper part of the side surface 1c adjacent to the upper surface 1a, which is positioned more to inside of the semiconductor substrate 1.

In the laser irradiation process, the laser beam L to be focused on the focusing plane 3 enters the semiconductor substrate 1 from the flat lower surface 1b, which is on an inner side of the curved end surface 1d of the semiconductor substrate 1. Therefore, in the laser irradiation process, the laser beam L can be favorably focused also on both end portions of the focusing plane 3 of the semiconductor substrate 1.

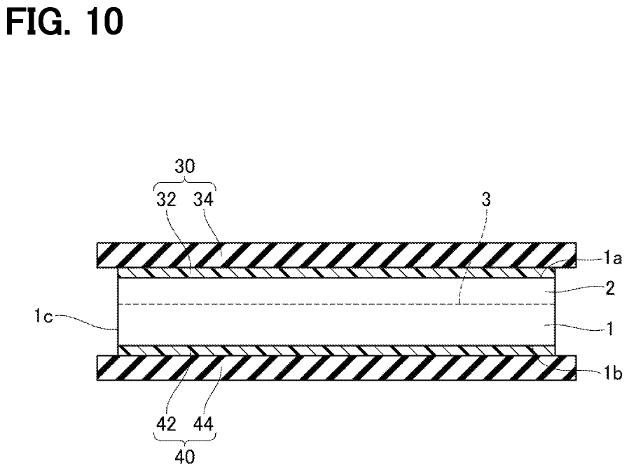

As shown in FIG. 10, the first deformation restriction layer 30 may include an adhesive layer 32 and a support substrate 34. The adhesive layer 32 is made of an organic material. Although not particularly limited, the adhesive layer 32 may be, for example, a double-sided tape which is generally used in a semiconductor manufacturing process. The support substrate 34 is fixed to the upper surface 1a of the semiconductor substrate 1 via the adhesive layer 32, and is made of a material having a Young's modulus higher than that of the semiconductor substrate 1. The support substrate 34 is a flat plate-shaped substrate extending parallel to the main surface of the semiconductor substrate 1. The support substrate 34 extends laterally beyond the side surface 1c of the semiconductor substrate 1. The support substrate 34 is not particularly limited, but may be, for example, a glass substrate or a sapphire substrate. The second deformation restriction layer 40 also includes an adhesive layer 42 and a support substrate 44. The adhesive layer 42 and the support substrate 44 of the second deformation restriction layer 40 can be made of the same material as the adhesive layer 32 and the support substrate 34 of the first deformation restriction layer 30, respectively.

Each of the deformation restriction layers 30 and 40 includes the support substrate 34 or 44 having a high Young's modulus. Therefore, even if the nitrogen gas is generated inside the semiconductor substrate 1 during the laser irradiation process, deformation of the semiconductor substrate 1 is restricted.

The techniques described hereinabove are summarized as follows. It should be noted that the technical elements described below are independent technical elements and exhibit technical usefulness alone or in various combinations, and are not limited to the combinations described herein.

In an embodiment of the present disclosure, in a manufacturing method of a semiconductor device, a first deformation restriction layer 30 and a second deformation restriction layer 40 are formed on a first main surface 10a and a second main surface 10b of a semiconductor substrate 1 on which a device structure 10 has been formed adjacent to the first main surface 10a. A laser beam L is applied through the second deformation restriction layer 40 so as to irradiate a plane 3 extending at a predetermined depth inside the semiconductor substrate 1 with the laser beam L. A device layer 2, which is a part of the semiconductor substrate 1 including the device structure 10 and the first main surface 10a, is peeled off from a remaining part of the semiconductor substrate 1 along the plane 3 irradiated with the laser beam L.

In an embodiment of the present disclosure, in the manufacturing method, at least one of the first deformation restriction layer 30 and the second deformation restriction layer 40 may include an organic layer made of an organic material.

In an embodiment of the present disclosure, in the manufacturing method, at least one of the first deformation restriction layer 30 and the second deformation restriction layer 40 may include a support substrate 34, 44. The support substrate 34, 44 may have a Young's modulus higher than that of the semiconductor substrate 1.

In an embodiment of the present disclosure, in the manufacturing method, the semiconductor substrate 1 may have a curved end surface 1d having a curved shape on a peripheral end of the second main surface 1b. In the forming of the first deformation restriction layer 30 and the second deformation restriction layer 40, the second deformation restriction layer 40 may be formed so as to cover the covered end surface 1d.

In an embodiment of the present disclosure, in the manufacturing method, the second deformation restriction layer 40 may be formed so as not to cover a portion of the side surface of the semiconductor substrate corresponding to the plane extending at the predetermined depth.

In an embodiment of the present disclosure, in the manufacturing method, before the laser beam L is applied, a peripheral end of the first main surface 1a of the semiconductor substrate 1 may be removed so that a first part of a side surface 1c of the semiconductor substrate 1 adjacent to the first main surface 1a is located on an inner side than a second part of the side surface 1c adjacent to the second main surface 1b of the semiconductor substrate 1. When the laser beam L is applied, a portion of the semiconductor substrate 1 corresponding to the plane extending at the predetermined depth is exposed on the first part of the side surface 1c. That is, the laser beam L is applied so that the plane extending at the predetermined depth is positioned at the first part of the side surface 1c.

In an embodiment of the present disclosure, in the manufacturing method, the semiconductor substrate 1 may be a nitride semiconductor substrate.

While only the selected exemplary embodiment and examples have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiment and examples according to the present disclosure is provided for illustration only, and not for the purpose of limiting the disclosure as defined by the appended claims and their equivalents.

What is claimed is:

1. A manufacturing method of a semiconductor device, comprising:
forming a first deformation restriction layer and a second deformation restriction layer on a first main surface and a second main surface of a semiconductor substrate, the first main surface being opposite to the second main surface, and the semiconductor substrate having a device structure formed adjacent to the first main surface;
applying a laser beam through the second deformation restriction layer on the second main surface of the semiconductor substrate so as to irradiate a plane extending at a predetermined depth inside of the semiconductor substrate with the laser beam; and
peeling off a device layer that is a part of the semiconductor substrate including the first main surface and the device structure from a remaining layer of the semiconductor substrate along the plane irradiated with the laser beam.

2. The manufacturing method according to claim 1, wherein
at least one of the first deformation restriction layer and the second deformation restriction layer includes an organic layer made of an organic material.

3. The manufacturing method according to claim 1, wherein
at least one of the first deformation restriction layer and the second deformation restriction layer includes a support substrate, and
the support substrate has a Young's modulus higher than that of the semiconductor substrate.

4. The manufacturing method according to claim 1, wherein
the semiconductor substrate has a curved end surface having a curved shape at a peripheral end of the second main surface, and
in the forming of the first deformation restriction layer and the second deformation restriction layer, the second deformation restriction layer is formed so as to cover the curved end surface.

5. The manufacturing method according to claim 4, wherein
in the forming of the first deformation restriction layer and the second deformation restriction layer, the second deformation restriction layer is formed so as not to cover a portion of a side surface of the semiconductor substrate, the portion corresponding to the plane extending at the predetermined depth and irradiated with the laser beam.

6. The manufacturing method according to claim 1, further comprising:
before the applying of the laser beam, removing a peripheral end of the first main surface of the semiconductor substrate so that a first part of a side surface of the semiconductor substrate adjacent to the first main surface is located on an inner side of the semiconductor substrate than a second part of the side surface of the semiconductor substrate adjacent to the second main surface in a planar direction of the semiconductor substrate, wherein
in the applying of the laser beam, the laser beam is applied so that the plane extending at the predetermined depth inside the semiconductor substrate is positioned at the first part of the side surface.

7. The manufacturing method according to claim 1, wherein
the semiconductor substrate is a nitride semiconductor substrate.
